(19) United States
(12) Patent Application Publication
(10) Pub. No.: US 2006/0269847 A1
(43) Pub. Date: Nov. 30, 2006

(54) BINDING OF HARD PELLICLE STRUCTURE TO MASK BLANK AND METHOD

(75) Inventors: Steven J. Holmes, Guilderland, NY (US); Kurt R. Kimmel, Waterford, NY (US)

Correspondence Address: FREDERICK W. GIBB, III;GIBB INTELLECTUAL PROPERTY LAW FIRM, LLC, 2568-A RIVA ROAD, SUITE 304, ANNAPOLIS, MD, 21401, US

(73) Assignee: INTERNATIONAL BUSINESS MACHINES CORPORATON, Armonk, NY (US)

(21) Appl. No.: 10/908,755

(22) Filed: May 25, 2005

(51) Int. Cl. A47G 1/12; G03F 1/14; G03F 1/00

(52) U.S. Cl. 430/5; 428/14

(57) ABSTRACT

An apparatus and method for attaching a pellicle to a mask for use in optical lithography comprises a lithographic mask; a pellicle ring; and a binding layer having a thickness of less than 100 nanometers between the pellicle ring and the lithographic mask. The binding layer comprises a graded oxide layer or anodic oxide layer. Alternatively, the binding layer comprises a polymer having a material composition capable of being vapor deposited, wherein the polymer comprises a maleic anhydride polymer. Still alternatively, the binding layer comprises a polymer having a uniform material composition. Another embodiment provides that the binding layer comprises a polymer having a material composition capable of being reactive with a bonding agent. Additionally, the pellicle ring comprises a pellicle and a pellicle frame, wherein the method further comprises applying a binding layer having a thickness of less than 100 nanometers between the pellicle and the pellicle frame.

### BACKGROUND OF THE INVENTION

1. Field of the Invention

The embodiments of the invention generally relate to semiconductor device processing, and more particularly, to the use of pellicles to protect photoresist masks and/or reticles during semiconductor device processing.

2. Description of the Related Art

A pellicle is a protective structure that is applied to a photoresist mask or a reticle. Ideally, a pellicle covers the photoresist mask or reticle and prevents contaminants from reaching the underlying mask surface. Thus, a properly placed pellicle can help in reducing the occurrence of wafer defects during clean room stepper focus or printing processing.

As photolithography processes for the fabrication of semiconductor devices continue to scale to the sub 100 nm regime, it is desirable to reduce the exposure wavelength from 193 nm to 157 nm and below in order to provide a capability for enhanced resolution and depth of focus process latitude. However, there may be technical problems associated with a migration to a 157 nm exposure wavelength due to the strong absorbance of many commonly used optical materials at this wavelength. For example, it is often desirable to substitute CaF₂ optical materials for the typically used silicon dioxide materials for lens fabrication. Thus, new polymers for photoresist masks should be developed to provide sufficient transparency, and new pellicle materials should be developed due to possible degradation and film thickness changes of conventional pellicle materials upon irradiation at 157 nm.

Some conventional solutions propose that a “hard” pellicle of silicon dioxide be used as a replacement for the typical conventional organic polymer type of pellicle material for 157 nm lithography. Unfortunately, this thick quartz pellicle typically functions as an optical element in the exposure system due to its greater thickness than other conventional pellicles, and is generally fabricated and mounted to the mask blank to precise tolerance values in order to avoid degradation of the aerial image during printing. Typical pellicle mounting procedures use a thick layer of a glue-like adhesive which is generally not well controlled (i.e., the thickness varies across the mask), such that the tolerance values required for mounting the hard pellicle cannot generally be attained.

A major challenge in the use of pellicles has been the mounting of the pellicle frame to the mask itself since the integrated structure is ideally extremely flat, parallel, and configured without local distortions. As mentioned, using standard adhesives or gaskets has thus far proven generally inadequate to meet the stringent specifications necessary due to stress-induced distortions and the inability to maintain tolerances for the various materials involved. Therefore, there remains a need for a new technique of bonding a pellicle to a pellicle frame and bonding a pellicle frame to a photoresist mask or reticle, which overcomes the limitations of the conventional approaches.

### SUMMARY OF THE INVENTION

In view of the foregoing, an embodiment of the invention provides an apparatus for attaching a pellicle to a mask for use in optical lithography comprising a lithographic mask; a pellicle ring; and a binding layer having a thickness of less than 100 nanometers between the pellicle ring and the lithographic mask. In one embodiment, the binding layer comprises a graded oxide layer. In another embodiment, the binding layer comprises an anodic oxide layer. In still another embodiment, the binding layer comprises a polymer having a material composition capable of being vapor deposited, wherein the polymer comprises a maleic anhydride polymer. In yet another embodiment, the binding layer comprises a polymer having a uniform material composition. Another embodiment provides that the binding layer comprises a polymer having a material composition capable of being reactive with a bonding agent. Furthermore, the pellicle ring comprises a pellicle; a pellicle frame; and a binding layer having a thickness of less than 100 nanometers between the pellicle and the pellicle frame.

Another embodiment of the invention provides a reticle comprising an outer surface; a pellicle ring; and a binding layer having a thickness of less than 100 nanometers between the outer surface and the pellicle ring. In one embodiment, the binding layer comprises a graded oxide layer. In another embodiment, the binding layer comprises an anodic oxide layer. Preferably, the binding layer comprises a polymer having a material composition capable of being vapor deposited, wherein the polymer may comprise a maleic anhydride polymer. Furthermore, the binding layer preferably comprises a uniform thickness. Additionally, in one embodiment the binding layer may comprise a polymer having a material composition capable of being reactive with a bonding agent. Moreover, the pellicle ring may comprise a pellicle; a pellicle frame; and a binding layer having a thickness of less than 100 nanometers between the pellicle and the pellicle frame.

Another aspect of the invention provides a method for attaching a pellicle to a mask for use in optical lithography, wherein the method comprises applying a binding layer having a thickness of less than 100 nanometers on each of a pellicle ring and a lithographic mask; and attaching the pellicle ring to the lithographic mask. In one embodiment, the binding layer comprises a graded oxide layer. In another embodiment, the binding layer comprises an anodic oxide layer. In still another embodiment, the binding layer comprises a polymer having a material composition capable of being vapor deposited, wherein the polymer comprises a maleic anhydride polymer. In yet another embodiment, the binding layer comprises a polymer having a uniform material composition. Another embodiment provides that the binding layer comprises a polymer having a material composition capable of being reactive with a bonding agent. The method further comprises applying heat to the binding layer during the attaching of the pellicle ring to the lithographic mask. Additionally, the pellicle ring comprises a pellicle and a pellicle frame, wherein the method further comprises applying a binding layer having a thickness of less than 100 nanometers between the pellicle and the pellicle frame.

Still another aspect of the invention provides a method for attaching a pellicle to a mask for use in optical lithography, wherein the method comprises doping a pellicle ring with a cation material; attaching the pellicle ring to a metal lithographic mask; heating the pellicle ring; applying an electrical bias to the pellicle ring; and forming an oxide at an interface between the attached pellicle ring and metal lithographic mask, wherein the cation material may comprise sodium. Furthermore, in one embodiment, the method further comprises clamping the pellicle ring to the metal lithographic mask.

The embodiments of the invention provide a method and a structure for creating a bond between a pellicle frame and a mask, and between the pellicle and the pellicle frame, which can achieve the tolerance values required for the mounting of the hard pellicle to the mask blank with high uniformity for 157 nm lithography. Specifically, the embodiments of the invention achieves this by using a thin nanolayer of binding material such as a nanoglue or adhesive, which can be uniformly vapor deposited in a highly controlled manner to create very uniform adhesive thicknesses on the bonding areas across the mask. Furthermore, an alternative embodiment of the invention provides a technique of joining the mask and pellicle frame without any intermediate material. Specifically, the second embodiment utilizes anodic bonding which generally grows a mutual graded-oxide at the interface of two appropriate materials (i.e., sodium and silicon and/or sodium and chromium) in intimate contact with one another and processed accordingly.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 illustrates schematic diagram of a first processing step for attaching a pellicle to a lithographic mask according to a first embodiment of the invention;

FIG. 2 illustrates schematic diagram of a second processing step for attaching a pellicle to a lithographic mask according to the first embodiment of the invention;

FIG. 3 illustrates schematic diagram of a third processing step for attaching a pellicle to a lithographic mask according to the first embodiment of the invention;

FIG. 4 illustrates schematic diagram of a fourth processing step for attaching a pellicle to a lithographic mask according to the first embodiment of the invention;

FIG. 5 illustrates a schematic diagram of a fifth processing step for attaching a pellicle to a lithographic mask according to the first embodiment of the invention;

FIG. 6 illustrates schematic diagram of a first processing step for attaching a pellicle to a lithographic mask according to a second embodiment of the invention;

FIG. 7 illustrates schematic diagram of a second processing step for attaching a pellicle to a lithographic mask according to a second embodiment of the invention;

FIG. 8 illustrates schematic diagram of a third processing step for attaching a pellicle to a lithographic mask according to the second embodiment of the invention;

FIG. 9 illustrates schematic diagram of a fourth processing step for attaching a pellicle to a lithographic mask according to the second embodiment of the invention;

FIGS. 10(A) and 10(B) illustrate schematic diagrams of alternate processing steps, which may be used according to the first or second embodiments of the invention;

FIG. 11(A) is a flow diagram illustrating a method of a preferred embodiment of the invention; and

FIG. 11(B) is a flow diagram illustrating a method of an alternate embodiment of the invention.

### DETAILED DESCRIPTION OF PREFERRED EMBODIMENTS OF THE INVENTION

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

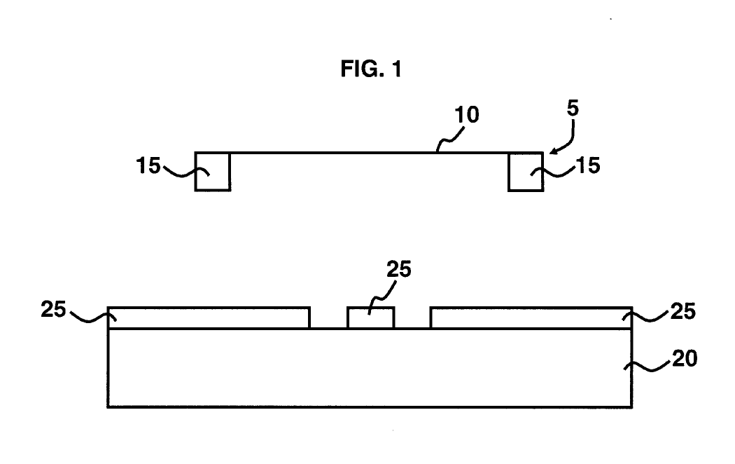

As mentioned, there remains a need for a new technique of bonding a pellicle to a pellicle frame and bonding a pellicle frame to a photoresist mask or reticle, which overcomes the limitations of the conventional approaches. The embodiments of the invention achieve this by providing a method and a structure for creating a bond between a pellicle frame and a mask frame, and between the pellicle and the pellicle frame, which can achieve the tolerance values required for the mounting of the hard pellicle to the mask blank with high uniformity for 157 nm lithography. Referring now to the drawings and more particularly to FIGS. 1 through 11(B) where similar reference characters denote corresponding features consistently throughout the figures, there are shown preferred embodiments of the invention.

A first embodiment is shown in FIGS. 1 through 5 utilizes a maleic anhydride polymer 30, which is deposited from a plasma jet as a thin layer of polymer which is reactive to amines. When two surfaces 15, 25 are coated with the maleic anhydride polymer 30 and reacted with multifunctional amines 35, the polymer 30 acts as an adhesive 60 to bind the surfaces 15, 25 together.

Specifically, as shown in FIG. 1, a pellicle 10 is attached to a pellicle frame 15 thereby forming a pellicle ring structure 5. The pellicle ring 5 is positioned over a preferably opaque quartz lithographic mask 25, which is formed over an underlying substrate 20. Preferably, the pellicle frame 15 comprises a sodium-containing glass, such as Pyrex™-type borosilicate, for example. Preferably, the substrate 20 comprises silicon dioxide and the lithographic mask 25, which may be a binary or attenuated phase shifting mask blank, comprises an upper layer of silicon, chromium, or other appropriate oxidizable metal material (not shown) that can react with sodium-containing glass. Any practical deposition method may be used to deposit the layer of silicon or chromium on the mask 25; e.g., sputtering, evaporation, ion beam deposition, electroplating etc.

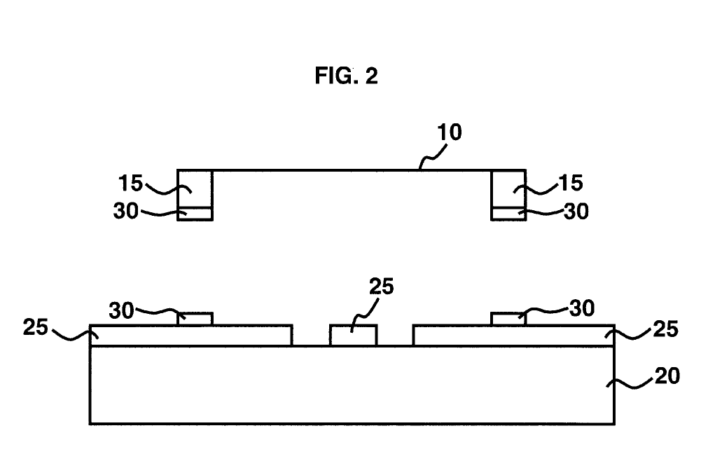

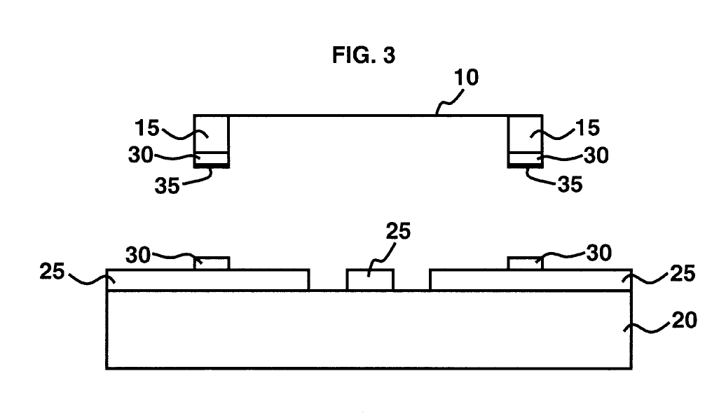

Next, as illustrated in FIG. 2, a maleic anhydride polymer 30 is vapor deposited to the pellicle frame 15 (on a side opposite where the pellicle frame 15 joins the pellicle 10) and a correspondingly aligned area(s) of the lithographic mask 25. Next, as shown in FIG. 3, an amine dendrimer 35 is applied to the maleic anhydride polymer 30 on the pellicle frame 15. The pellicle frame 15 may be dipped in a liquid solution containing the amine dendrimer 35 in order to apply the amine dendrimer 35 to the maleic anhydride polymer 30.

The maleic anhydride polymer 30 is deposited using a plasma jet vapor deposition tool. Preferably, the maleic anhydride polymer film 30 is activated for adhesion by contacting it with a methanol solution of amine dendrimer 35 at approximately 25° C. for 30-60 minutes. In this regard, a vapor of maleic anhydride at 3-10 torr is provided and a carrier gas of argon may be used if desired to dilute the reagent. The vapor is passed through a plasma jet nozzle, creating a jet spray of plasma-excited maleic anhydride monomer in a narrow beam of 0.2-2.0 mm.

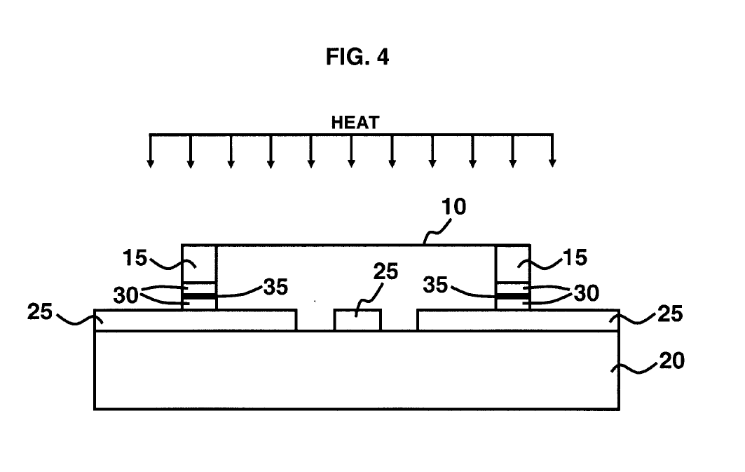

This beam of reagent is then guided across the surface of the patterned photomask 25 in the desired area(s) to bind the pellicle ring 5 to the photomask 25. The substrate temperature is preferably 25° C. during film deposition. After treatment with the amine dendrimer solution, the substrate 20, mask 25, and pellicle ring 5 are rinsed with methanol and placed together for bonding. Then, when the pellicle frame 15 with the attached maleic anhydride polymer 30 and amine dendrimer 35 is brought into contact with the maleic anhydride polymer 30 on the mask 25, heat is applied thereon to dry/cure the maleic anhydride polymer 30, as shown in FIG. 4. When two such activated layers (maleic anhydride polymer 30 and amine dendrimer 35) are placed in contact with one another and heated, they form a cross-linked material which acts as an adhesive binding layer.

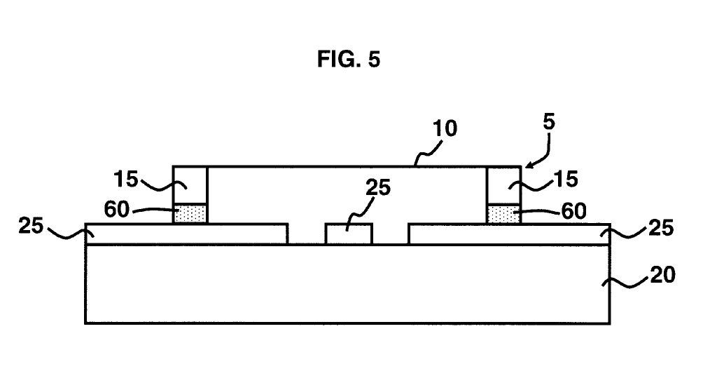

Preferably, the bonding process is carried out at approximately 120° C. for approximately 1-10 hours to complete the adhesive formation process. Thereafter, the maleic anhydride polymer 30 is fully cured thereby bonding the pellicle ring 5 to the mask 25. The thickness of the resulting adhesive binding layer 60, shown in FIG. 5, can range between 20 nm-300 nm, as desired, but is preferably less than 100 nanometers.

The use of the plasma jet spray tool to deposit the maleic anhydride polymer 30 allows the resulting adhesive layer 60 to be selectively formed in areas of the mask 25 and pellicle frame 15 where the bonding occurs. Accordingly, it would be undesirable to form the adhesive layer 60 in other areas of the mask blank 25 or pellicle frame 15 as it would interfere with the formation of the aerial image during the printing process. Furthermore, general types of plasma deposition equipment would not be useful for this process due to the lack of an ability to precisely control the areas of adhesive deposition.

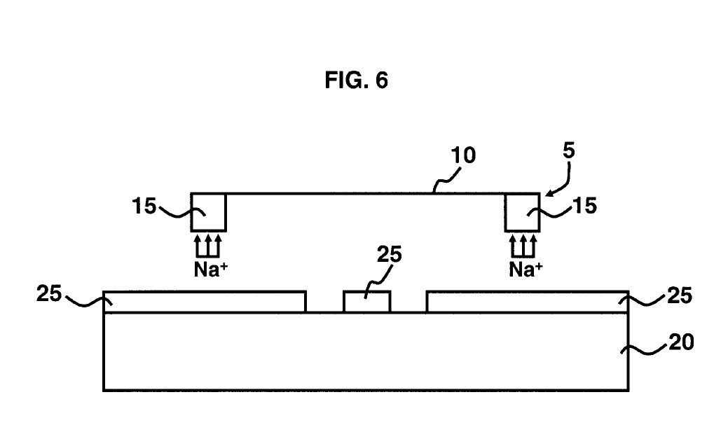

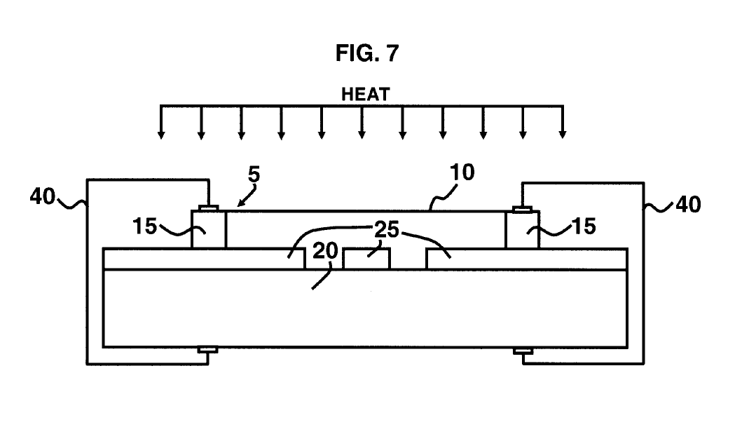

In a second embodiment, shown in FIGS. 6 through 9, anodic bonding is used to form the bond between the pellicle ring 5 and the mask 25. As illustrated in FIG. 6, in the second embodiment, the pellicle ring 5 is positioned over the mask 25, wherein the pellicle frame 15 is doped with sodium (Na+), but other mobile, reactive cations may be suitable. Thereafter, as shown in FIG. 7, the pellicle ring 5 and the mask 25 are placed in contact with one another, whereby the gravitational force acting on the pellicle ring 5 is sufficient to provide the resulting anodic bonding between the pellicle frame 15 and the mask 25 because the surfaces of both the pellicle frame 15 and mask 25 are extremely flat and smooth. However, forced clamping via mechanical or other means 40 (liquid pressure, gas pressure, electric field, magnetic field, etc.) can aid in providing good contact between the surfaces of the pellicle frame 15 and the mask 25.

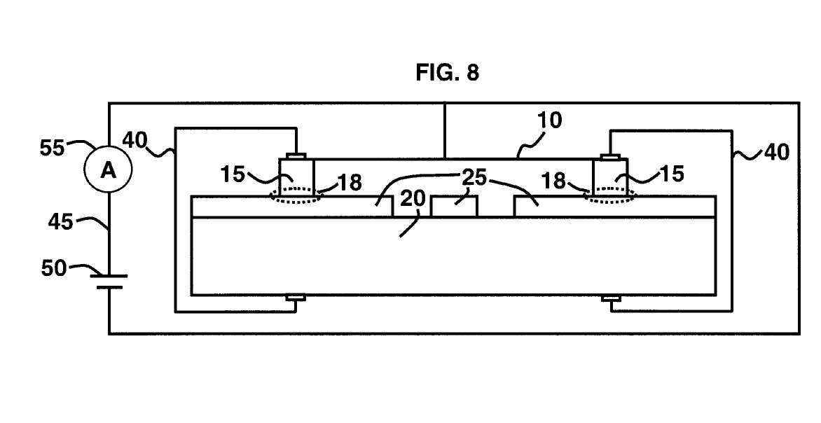

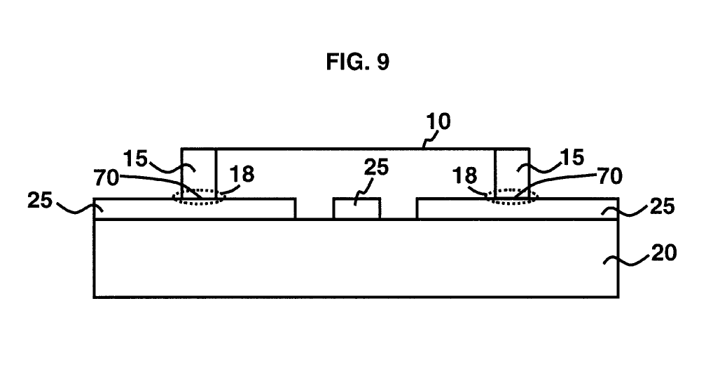

Additionally, as shown in FIG. 7, heat is applied to the apparatus, and more particularly to the doped sodium at a minimum of approximately 170° C. The application of heat allows the sodium to become interstitially mobile and, as shown in FIG. 8, under the influence of a moderate DC bias 50 (at preferably 2-5 kV for 1-2 hours), the doped sodium on the pellicle frame 15 moves toward an interface 18 between the pellicle frame 15 and the underlying mask 25, where it (the sodium) reacts with the metal in the mask 25 to create an oxide 70 shown in FIG. 9. The DC bias 50 should preferably be applied while the pellicle frame 15 is hot or warm. The oxide 70 encompasses that area of the pellicle frame 15 comprising the doped sodium. Hence, the oxide 70 only forms at the interface 18 between the pellicle frame 15 and the metal on the mask 25.

Again, with reference to FIG. 8, the electrical bias 50 is applied at the interface 18. An electronic current (A) feedback monitoring circuit 55, which is controlled by an electronic control circuit 45, detects the interaction between the pellicle frame 15 and the metal mask 25. The output of the electronic current feedback monitoring circuit 55 directly reflects the interaction of the pellicle frame 15 and the metal mask 25. Thereafter, the electrical bias 50 is removed, and the apparatus is allowed to cool slowly. Next, if clamps 40 are used, they are removed.

The oxide 70 grows with the side effect of joining the two materials (doped/heated sodium on the pellicle frame 15 and the metal mask 25). The interface 18 in microscopic profile looks like a graded oxide meaning there is a gradient of oxide character as you move from one surface being bonded through the depth of the oxide 70 toward the other surface. The bond is hermetic, irreversible, and quite mechanically strong.

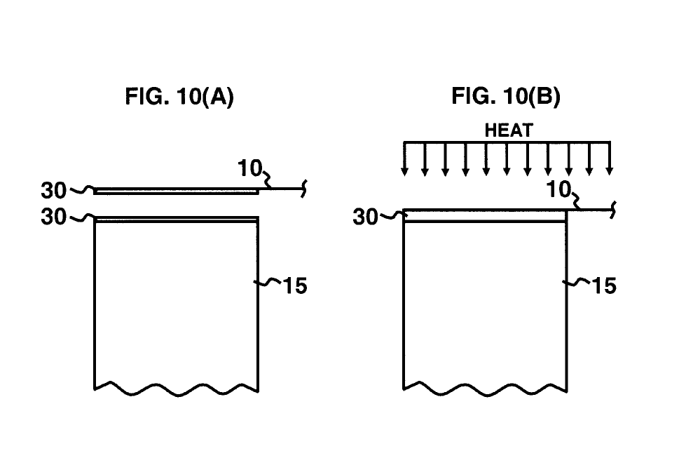

In one embodiment, as further illustrated in FIGS. 10(A) and 10(B), a maleic anhydride polymer 30 is activated with an amine (not shown in FIGS. 10(A) and 10(B)) and is vapor deposited on each of the pellicle 10 and pellicle frame 15, and upon heating, are joined together, thereby attaching the pellicle 10 to the pellicle frame 15. Alternatively, with regard to the first embodiment, the maleic anhydride polymer 30 may be vapor deposited to both ends of the pellicle frame 15 and to the pellicle 10 during one processing step, thereby further saving processing time.

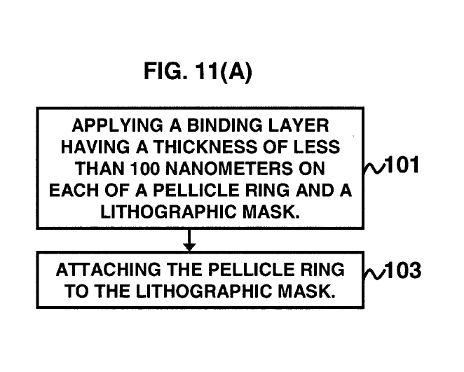

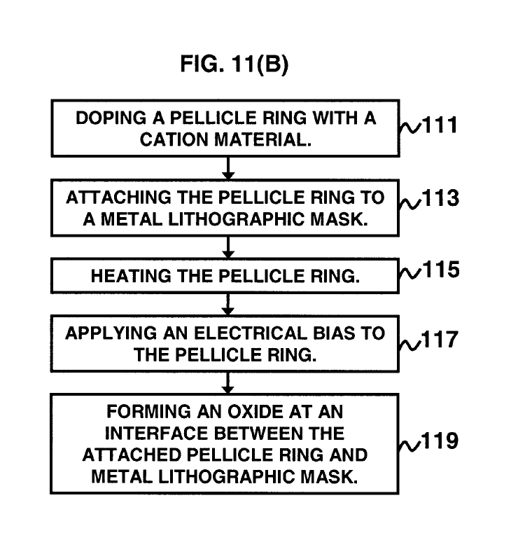

Another aspect of the invention is illustrated in the flowcharts of FIGS. 11(A) and 11(B), which include descriptions which refer to components provided in FIGS. 1 through 10(B). FIG. 11(A) illustrates a method for attaching a pellicle 10 to a mask 25 for use in optical lithography, wherein the method comprises applying (101) a binding layer 60, 70 having a thickness of less than 100 nanometers on each of a pellicle ring 5 and a lithographic mask 25 and attaching (103) the pellicle ring 5 to the lithographic mask 25. In one embodiment, the binding layer 70 comprises a graded oxide layer. In another embodiment, the binding layer 70 comprises an anodic oxide layer. In still another embodiment, the binding layer 60 comprises a polymer 30 having a material composition capable of being vapor deposited, wherein the polymer 30 comprises a maleic anhydride polymer. In yet another embodiment, the binding layer 60 comprises a polymer 30 having a uniform material composition. Another embodiment provides that the binding layer 30 comprises a polymer having a material composition capable of being reactive with a bonding agent 35. The method further comprises applying heat to the binding layer 60 during the attaching of the pellicle ring 5 to the lithographic mask 25. Additionally, the pellicle ring 5 comprises a pellicle 10 and a pellicle frame 15, wherein the method further comprises applying a binding layer 30 having a thickness of less than 100 nanometers between the pellicle 10 and the pellicle frame 15.

FIG. 11(B) illustrates a method for attaching a pellicle 10 to a mask 25 for use in optical lithography, wherein the method comprises doping (111) a pellicle ring 5 with a cation material; attaching (113) the pellicle ring 5 to a metal lithographic mask 25; heating (115) the pellicle ring 5; applying (117) an electrical bias to the pellicle ring 5; and forming (119) an oxide 70 at an interface 18 between the attached pellicle ring 5 and metal lithographic mask 25, wherein the cation material may comprise sodium. Furthermore, in one embodiment, the method further comprises clamping the pellicle ring 5 to the metal lithographic mask 25.

The embodiments of the invention provide a method and a structure for creating a bond between a pellicle frame 15 and a mask 25, and between the pellicle 10 and the pellicle frame 15, which can achieve the tolerance values required for the mounting of the hard pellicle 10 to the mask blank 25 with high uniformity for 157 nm lithography. Specifically, the embodiments of the invention achieves this by using a thin nanolayer of binding material 60 such as a nanoglue or adhesive, which can be uniformly vapor deposited in a highly controlled manner to create very uniform adhesive thicknesses on the bonding areas across the mask 25. Furthermore, an alternative embodiment of the invention provides a technique of joining the mask 25 and pellicle frame 15 without any intermediate material. Specifically, the second embodiment utilizes anodic bonding which generally grows a mutual graded-oxide 70 at the interface 18 of two appropriate materials (i.e., sodium and silicon and/or sodium and chromium) in intimate contact with one another and processed accordingly.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

What is claimed is:

1. A reticle comprising:
an outer surface;
a pellicle ring; and
a binding layer having a thickness of less than 100 nanometers between said outer surface and said pellicle ring.

2. The reticle of claim 1, wherein said binding layer comprises a graded oxide layer.

3. The reticle of claim 1, wherein said binding layer comprises an anodic oxide layer.

4. The reticle of claim 1, wherein said binding layer comprises a polymer having a material composition capable of being vapor deposited.

5. The reticle of claim 1, wherein said binding layer comprises a uniform thickness.

6. The reticle of claim 1, wherein said binding layer comprises a polymer having a material composition capable of being reactive with a bonding agent.

7. The reticle of claim 4, wherein said polymer comprises a maleic anhydride polymer.

8. The reticle of claim 1, wherein said pellicle ring comprises:
a pellicle;
a pellicle frame; and
a binding layer having a thickness of less than 100 nanometers between said pellicle and said pellicle frame.

9. A method for attaching a pellicle to a reticle, said method comprising:
forming a binding layer having a thickness of less than 100 nanometers on each of a pellicle ring and a reticle; and
attaching said pellicle ring to said reticle.

10. The method of claim 9, wherein said binding layer comprises a graded oxide layer.

11. The method of claim 9, wherein said binding layer comprises an anodic oxide layer.

12. The method of claim 9, wherein said binding layer comprises a polymer having a material composition capable of being vapor deposited.

13. The method of claim 9, wherein said binding layer comprises a uniform thickness.

14. The method of claim 9, wherein said binding layer comprises a polymer having a material composition capable of being reactive with a bonding agent.

15. The method of claim 12, wherein said polymer comprises a maleic anhydride polymer.

16. The method of claim 9, further comprising applying heat to said binding layer during said attaching of said pellicle ring to said reticle.

17. The method of claim 9, wherein said pellicle ring comprises a pellicle and a pellicle frame, wherein said method further comprises forming a binding layer having a thickness of less than 100 nanometers between said pellicle and said pellicle frame.

18. A method for attaching a pellicle to a lithographic mask comprising a metal surface, said method comprising:
doping a pellicle ring with a cation material;
placing said pellicle ring in contact with the metal surface of said lithographic mask;
heating said pellicle ring;
applying an electrical bias to said pellicle ring; and
forming an oxide at an interface between the attached pellicle ring and metal lithographic mask.

19. The method of claim 18, further comprising clamping said pellicle ring to said metal lithographic mask.

20. The method of claim 18, wherein said cation material comprises sodium.
